(19) United States
(12) Patent Application Publication
(10) Pub. No.: US 2007/0108584 A1
(43) Pub. Date: May 17, 2007

(54) Transmitter module with improved heat dissipation

(76) Inventors: Holger Fluhr, Graz (AT); Christian Block, Stainz (AT); Christian Hoffmann, Deutschlandsberg (AT)

Correspondence Address: FISH & RICHARDSON PC, P.O. BOX 1022, MINNEAPOLIS, MN, 55440-1022, US

(21) Appl. No.: 10/570,189

(22) PCT Filed: Aug. 12, 2004
(86) PCT No.: PCT/EP04/09065

§ 371 Date: Jun. 23, 2006

(30) Foreign Application Priority Data
Sep. 2, 2003 (DE) 103 40 438.4

(51) Int. Cl. H01L 23/48

(52) U.S. Cl. 257/690

(57) ABSTRACT

A transmitter module for mobile radio applications includes a multilayer module substrate with levels of metallization and intervening dielectric stacks in which a circuit is implemented by structuring the levels of metallization. In or on the module substrate, at least one HF filter or adjustment network is implemented. On the underside of the module substrate, a cutout, in which a chip element is soldered in a flip-chip-arrangement, is provided. The rear of the chip element pointing to the outside displays a metallization that makes a good thermal contact of the chip element with extrinsic circuit surroundings possible.

### TECHNICAL FIELD

The application relates to a transmitter module for mobile radio applications that is constructed on a multilayered substrate that includes at least one circuit integrated into the multilayered substrate.

### BACKGROUND

Transmitter modules for mobile radio applications that are constructed on multilayered substrates with integrated wiring are known. A conventional transmitter module includes, for example, a power amplifier that is on an upper side of the module substrate and that is mounted as a bare chip (pure die) or as a housed component. The module substrate includes metallization layers that are structured and interconnected via through contacts. Dielectric layers are arranged between the metallization layers. By selecting suitable material for the dielectric layers, and suitable structuring of the metallization layers, passive components, such as conductor lines, resistors, capacitors and inductors can be constructed. These components can be connected horizontally within a metallization layer and vertically, to a circuit having several components, via through contacts that span several metallization layers. In the transmitter module, a matching network is integrated to transform the output impedance of the power amplifier, which may be the input impedance (typically 50 ohms) of components of external circuits.

A power switch module PSM may be integrated into the transmitter module. The power switch module, the matching network, TX filters, and transmit/receive switches are arranged on the upper side of the module substrate as discrete components.

Low pass filter TX modules are components that can be integrated into integrated reception filtering systems (e.g., in a power-switch-module with integrated filtering, PSiF). Also, reception filters are arranged, as discrete components, on an upper side of the module substrate and are interconnected with the module.

In transmitter modules with power amplifiers, significant amounts of heat dissipated from the power amplifiers must be diverted from the module to an external circuit or circuit board. In conventional modules, which integrate a power amplifier on the surface of the module substrate using wire bonding technology, heat dissipation is effected by thermal vias. That is, heat dissipation may occur by thermal connections that pass through the entire substrate, which initially divert heat to the underside of the module substrate and then to external circuits or other surroundings. The power amplifier is thus provided as a separate component, which is installed on a lead frame using wire bonding technology. This construction permits heat dissipation to occur directly through the metallic lead frame.

### SUMMARY

The transmitter module described herein provides improved heat dissipation. It neither contains nor requires thermal vias, additional heat conductors or heat sinks in the substrate. In addition, the embodiments enable miniaturization of the transmitter modules, and with it, enhanced vertical integration. Moreover, integration of a transmitter filter, power amplifier, and antenna switch reduces the space occupied by the transmitter module to that of a conventional antenna switch.

The transmitter module includes a cutout and/or recess on the underside of the module substrate, in which a chip element is arranged. Connection of the chip element with the module substrate is via flip-chip-construction so that the rear of the chip element near the periphery of the module forms a part of the underside of the module substrate, on which contacts are provided to connect to external circuits. This arrangement of the chip element brings the rear of the chip element into thermal contact with metallization and dissipates heat from the module to an external circuit. This construction does not employ thermal solder bumps as is usual in flip-chip-technology, which bumps can have disadvantages during high frequency (HF) operation.

In one aspect, the recess on the underside of the module substrate is at least partially filled with an electrically insulating under filler. Such an under filler can be applied as fluid reaction resin, such as casting resin, and has a low E-module. The chip element can thus be secured in the recess without requiring a large number of thermal solder bumps, which are particularly disadvantageous for HF properties of a power amplifier. Electric connection of the chip element to the module substrate is covered by the under filler and thereby protected. The under filler may be silicone resin, such as a polysiloxane.

Contact between the metallization on the rear of the chip element and the recess can be achieved through an electrically-conducting bulk filling material if the flip-chip-connection is insulated with the under filler and the recess is at least partially filled. The bulk filling material includes, e.g., electrically conducting particles such as metal particles, graphite, or plumbago filled resin, which fill the recess so that the rear of the chip element is covered. By virtue of this metallization, thermal contact with an external circuit can be produced by, for example, electrically conducting adhesive or soldering.

It is also possible to fill the recess completely with an electrically insulating under filler and/or introduce metallization layers over the rear of the chip element. Such metallization layers that at least cover the rear of the chip element can be formed by sputtering. It is also possible to reinforce the metallization layers galvanically.

In another aspect, a metallic cover for closing the recess is provided, which is in thermal contact with the rear of the chip element. Such a cover can be deposited while forming the rear of the chip element. The cover connects to the chip element and the underside of the module substrate, whereby a flip-chip-arrangement is simultaneously produced by soldering to soldering contacts in the recess. The recess can be tightly closed with the cover and no further under filler is necessary. It is also possible, however, to install the cover after assembling the chip elements in the recess on the underside of the module substrate, thereby covering the opening of the recess.

In another aspect, the chip element is equipped with layers of metallization on the rear before it is mounted on the module substrate. Alternatively, an already present backside metallization of the chip element can be used for this purpose. The metallization can then be directly connected with an external outer circuit for heat transfer by, for example, soldering or electrically conducting glue together with a heat sink. In this case, the recess around the chip element can still be at least partially filled with an under filler.

The transmitter module can include a low pass filter that operates as a transmitter filter and that is integrated inside of the module substrate. Circuits can be arranged on the upper side of the module substrate, which are discrete semiconductor components arranged using the flip-chip-technique or using conventional wire bonding technology. Switches are used for frequency band selection or for switchovers between transmit and receive mode so that an antenna is alternatively connected to a circuit with a transmit and/or receive path. These switches can be constructed as current-controlled devices, for example, as pin diodes, or as voltage-controlled Gallium arsenide switches. Also possible are CMOS switches, MEMS-switches or switches implemented in other circuitry techniques.

In another aspect, the transmitter module includes, in addition to the transmitter filter, another reception filter, which is arranged together with the switch on the surface of the module substrate. In the interior of the module substrate, there are adapter circuits with which the chip element constructed as a power amplifier is adjusted to the circuits. Such an adapter circuit allows for impedance adjustment from the output of the power amplifier at 50 ohms.

That reception filter can be constructed using a discrete component, such as an SAW-filter, a BAW-filter (Bulk Acoustic Wave), or ceramic filters. In another implementation, the transmitter filter can be integrated into a module substrate comprised of ceramic layers, where the transmitter serves as an LC-filter made of integrated inductors and capacitors, or as stripline filters by means of electromagnetically coupled conduits in the substrate.

### DESCRIPTION OF DRAWINGS

FIGS. 1 through 3 show transmitter modules in a cross-section of the underside of a module substrate with various metallizations,

FIG. 4 shows a transmitter module in a cross-section showing integrated components on the upper side of the module substrate,

FIG. 5 shows a transmitter module in a top view,

FIG. 6 shows a power amplifier on a lead frame in a cross-section.

### DETAILED DESCRIPTION

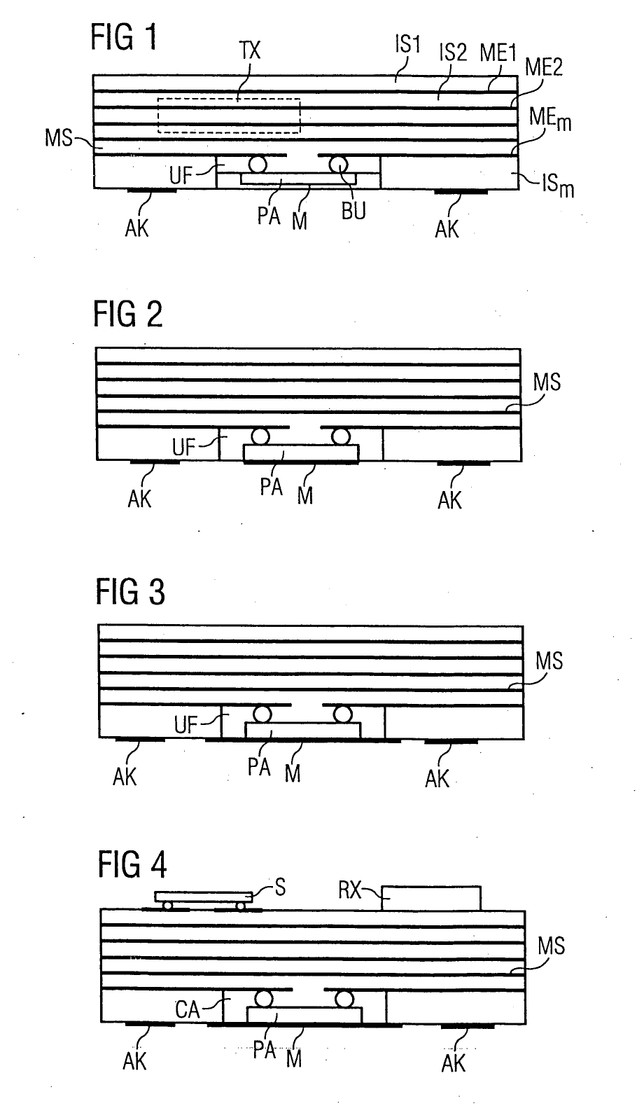

FIG. 1 shows a transmitter module. The transmitter module includes a multilayered module substrate that displays several layers of metallization ME1, ME2, . . . MEn, which are arranged between dielectric insulating layers IS1, IS2, . . . ISm. The dielectric layers can be dielectric ceramics. Integrated passive elements can be implemented by appropriate structuring of the metallization layers (ME) in the interior of the module substrate along with a low pass filter TX. This low pass filter is used as a transmitter filter in the transmitter module. By structuring the metallization layers that are not shown in more detail and throughput contacts (not shown in FIG. 1), with which electric connections between the metallization layers are created, additional circuits can be implemented in the interior of the module substrate and individual components can be interconnected.

On the underside of the module substrate, a cutout (CA) is formed (see also FIG. 4), within the lowermost dielectric layer (ISm). In the cutout (CA), there are electric connection surfaces to which a chip element (PA) is added via the flip-chip-technique. Bonding of the chip element and electric connection surfaces is implemented via spot soldering, for example, by means of soldering contacts BU. The chip element can be a power amplifier.

The cutout (CA) is partially filled with an under filler (UF) that electrically insulates the soldering contacts BU of the chip element. In addition to the under filler, an electrically conducting bulk filling material, for example, a reactive resin, that can fill the cutout (CA) to contact the lower upper surface of the module substrate and thereby cover the rear end of the chip element (PA) pointing to the outside. Via the metallization (M) resulting from the bulk filling material, the chip element (PA) can enter into thermal contact with an external circuit (not shown in FIG. 1), for example, with a heat sink (not shown in FIG. 1) on a circuit board, so that dissipated heat can be drawn outside the module. Outside contacts are provided for implementing electrical contact of the transmitter module with an exterior circuit. The outside contacts are on the underside of the module substrate (MS).

In addition to the components shown in the figures, additional circuits can be implemented in the inside of the module substrate. Moreover, discrete single components or integrated elements (chips) can be arranged on the upper side of the module substrate and electrically connected with the inside of the module substrate.

FIG. 2 shows another implementation, which, compared with FIG. 1, is distinguished by the type of metallization on the underside of the module substrate. In this example, the cutout (CA) is completely filled with an under filler (UF) so that the rear of the chip element remains uncovered. On the rear of the chip element (PA) pointing to the outside of PA, metallization is introduced, preferably before soldering the chip element to the module substrate (MS). Here too, the metallization can pass thermal heat loss of the chip element (PA) via good thermal contact and the metallization (M) to an external circuit.

FIG. 3 shows another implementation, in which the cutout (CA) is completely filled with an under filler (UF) after mounting the chip element (PA). The under filler and rear of the chip element (PA) are in contact with the underside of the module substrate (MS). Subsequently, metallization (M) is provided on the underside of the module substrate (M) by, for example, sputtering, a metal layer that can still be galvanically reinforced afterward. The metal layer can cover parts of the under filler and the underside of the module substrate in addition to the chip element.

FIG. 4 shows another implementation, in which the cutout (CA) is covered with a cover manufactured of, for example, sheet metal, that corresponds to the metallization (M). The metallization (M) and/or the cover can be tightly connected with the chip element (PA). For example, the two can be soldered together. It is also possible to mount the cover after soldering the chip element (PA) over the cutout (CA), preferably so that that cutout is tightly closed. To this end, the cover can be soldered to the underside of the module substrate or glued thereto. Thereby, the underside of the module substrate is preferably metallized to the connection site. It is also possible, however, to arrange the cover by means of other attachment methods on the underside of the module substrate (MS).

In the implementation of FIG. 4, components of the transmitter module are displayed that can also be present in the implementations shown in FIGS. 1 through 3. For example, an additional HF-filter constructed as a reception filter (RX) is installed on the upper side of the module substrate. The installation can take place via a surface mount device technique (“SMD-technique”), flip-chip-technique, or via wire bonding technology. The reception filter (RX) can also be attached to the module substrate (MS) via wire bonding technology.

A switch (S) constructed via an integrated semiconductor component (chip) can be implemented on the upper side of the module substrate. The switch enables a switch over of the transmitter module between transmit and receive mode and, in some cases, switch over between different transmit and receive bands. The element that implements the switch (S) can be installed in a flip-chip-arrangement or as an SMD on the module substrate (MS). It is also possible to attach the switch (S) and interconnect it with the transmitter via wire bonding technology.

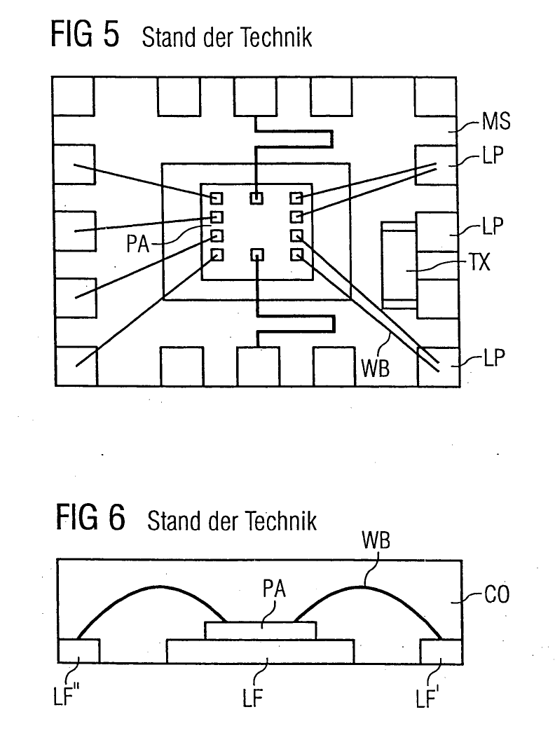

FIG. 5 shows a prior art transmitter module in which a chip element constructed as a power amplifier is mounted on a lead frame or a module substrate (MS) and is contacted by means of wire bonding technology with the module substrate. For this, electric connection surfaces on the upper side of the chip element (PA) are connected with corresponding leads or solder pads on the surface of the module substrate by means of wire bonding (WB). On the surface of the module substrate, another discrete SMD-element, for example a capacitor, is arranged here and also connected with the solder pads (LP). The connection contacts for connection with an external circuit are arranged on the non-visible underside of the module substrate. The dissipation of surplus and interfering heat loss from this chip element (PA) must here occur via the module substrate of (M) which is impeded by the dielectric layers of the module substrate. In many cases it is therefore necessary to provide thermal vias in the module substrate that can bring about a thermal dissipation throughout the module substrate.

FIG. 6 shows a prior art chip element (PA) constructed as a power amplifier that is installed on a lead frame (LF) and is electrically contacted with the lead frame (LF′, LF″) by a wire bonding (WB). The lead frame can be covered with casting material (CO) and be electrically insolated. Another integration to the transmitter module is possible here only by arranging further single components on the lead frame LF.

Other implementations are possible. For example, it is possible to integrate additional components that are not shown in the figures in, or on, the module and to implement additional circuits in the module substrate that support the functionality of transmitter modules. Also the type of metallization with which the chip element (PA) is in contact on the underside of the module substrate (MS) can be constructed in a manner other than that described herein. The chip element (PA) is preferably a power amplifier for the transmit mode of the transmitter modules, but can also be any other type of chip element (PA) whose dissipated heat should be output in order to avoid malfunctions or destruction. Transmitter modules can also include more than one chip element arranged in one or several cutouts on the underside of the module substrate.

1. A transmitter module comprising:
a transmitter filters;
a module substrate comprising multiple layers, the multiple layers comprising:
at least two metallization layers that define at least one component; and
insulating layers among the metallization layers;
wherein an underside of the module substrate has an edge that defines a cutout;
a chip element connected in flip-chip-arrangement with the at least one component via the cutout; and
metallization in contact with the chip element which diverts heat dissipated by the chip element.

2. The transmitter module of claim 1, further comprising an under filler that is electrically insulating, wherein the cutout is at least partially filled with the under filler.

3. The transmitter module of claim 2, further comprising a bulk filling material that is electrically conductive, wherein the bulk filling material is over the under filler and fills the cutout.

4. The transmitter module of claim 2, wherein the cutout is completely filled with the under filler.

5. The transmitter module of claim 1, wherein the metallization is on a rear side of the chip element.

6. The transmitter module of claim 1, wherein the metallization comprises a metallic cover enclosing the cutout at least partly.

7. The transmitter module of claim 5, wherein the metallization is sputtered on the rear side of the chip element.

8. The transmitter module of claim 1, wherein the metallization is in direct thermal contact with an external circuit.

9. The transmitter module of claim 1, wherein the metallization adheres to an external circuit that is thermally conductive.

10. The transmitter module of claim 1, further comprising an impedance adapter circuit, wherein the impedance adapter circuit is either integrated into an interior of the module substrate, or partially integrated into the interior of the module substrate.

11. The transmitter module of to claim 1, wherein the transmitter filter comprises a low pass filter that is integrated in an interior of the module substrate.

12. The transmitter module of to claim 11, further comprising switches integrated on an upper side of the module substrate, the switches enabling selection between at least one of transmitting and receiving equipment and between different frequency bands.

13. The transmitter module of claim 12, wherein the switches comprise as PIN diodes, GaAs switches, CMOS switches or MEMS switches.

14. The transmitter module according to claim 11, wherein the transmitter filter is integrated into the circuit in the interior of the module substrate; and
further comprising:
reception filters on an upper side of the module substrate; and
adapter circuits integrated into the module substrate.

15. The transmitter module of claim 1, wherein the module substrate comprises an LTCC ceramic, an HTCC ceramic or a laminate.

16. The transmitter module of claim 1, wherein the chip element comprises a power amplifier.

17. The transmitter module of claim 14, wherein the reception filters are SAW-filters, or BAW-filters, or ceramic filters.

18. The transmitter module of claim 15, wherein the module substrate further comprises an LC-filter comprising integrated inductors and capacitors.

19. The transmitter module of claim 15, wherein the module substrate further comprises a stripline filter comprising electromagnetically coupled conduits.

20. The transmitter module of claim 10, wherein the impedance adapter circuit comprises surface mount device elements, wherein the surface mount device elements are mounted on an upper side of the module substrate.

21. The transmitter module of claim 10, wherein the impedance adapter circuit comprises integrated passive components.
